(19) United States
(12) Patent Application Publication
(10) Pub. No.: US 2006/0263700 A1
(43) Pub. Date: Nov. 23, 2006

(54) Photo mask used for fabricating semiconductor device

(76) Inventor: Byoung Sub Nam, Chungcheongbuk-do (KR)

Correspondence Address: LADAS & PARRY LLP, 224 SOUTH MICHIGAN AVENUE, SUITE 1600, CHICAGO, IL, 60604, US

(21) Appl. No.: 11/159,022

(22) Filed: Jun. 22, 2005

(30) Foreign Application Priority Data
May 18, 2005 (KR) 10-2005-0041680

(51) Int. Cl. G03F 1/00

(52) U.S. Cl. 430/5

(57) ABSTRACT

Disclosed is a photo mask used for fabricating a semiconductor device, capable of ensuring a process margin for a photo process in a pattern region where it is difficult to use an assist feature. The photo mask includes a line/space pattern part for forming a line/space pattern on a wafer. The line/space pattern part includes an outermost pattern having a slice pattern so that so that the outermost pattern of the line/space pattern part is divided into two or more pattern segments.

### BACKGROUND OF THE INVENTION

1. Field of the Invention

The present invention relates to a photo mask used for fabricating a semiconductor device. More particularly, the present invention relates to a photo mask used for fabricating a semiconductor device, which can ensure a process margin in a pattern region where it is difficult to use an assist feature.

2. Description of the Prior Art

As generally known in the art, the outermost pattern in a line/space (L/S) pattern region, such as a drain selective line (DSL) and a source selective line (SSL) of a flash memory, has no process margin or has a very small process margin because a critical dimension (CD) of the outermost pattern rapidly varies according to focus variation. For this reason, an assist feature has been used in order to solve the process problems derived from the process margin of the outermost pattern.

FIG. 1 is a view illustrating a conventional photo mask having an assist feature used for fabricating a semiconductor device. In FIG. 1, reference numerals 2, 4, 5 and 10 represent an L/S pattern, an outermost pattern, an assist feature and a photo mask, respectively.

The assist feature 5 is provided in the photo mask 10 in order to ensure the process margin. However, as semiconductor devices have been highly integrated, there are following limitations when using the assist feature.

First, the assist feature needs to optimize an interval between the assist feature and a main pattern. If the assist feature is spaced far from the main pattern more than a predetermined distance, the interference effect between the assist feature and the main pattern may be lowered so that the usage efficiency of the assist feature may be attenuated. In contrast, if the assist feature is aligned closely to the main pattern in order to maximize the interference effect, a scum may be generated due to the assist feature.

Second, the assist feature needs to optimize a pattern size thereof. This is because the assist feature can maximize the interference effect without generating the scum on a wafer only when the pattern size of the assist feature is optimized.

Third, even if the optimum pattern size of the assist feature adaptable for a photo process is selected, it is necessary that the mask manufacturing company must deal with the optimum pattern size of the assist feature. Presently, the mask manufacturing company can deal with the pattern size in a range of about 40 to 50 nm. If the pattern size is smaller than the above range, it is difficult for the mask manufacturing company to deal with the pattern size. However, as the photo process has been currently developed from a KrF process (λ=248 nm) to an ArF process (λ=193 nm), the assist feature may generate scum on the wafer if the assist feature having the pattern size adaptable for the KrF process is used for the ArF process. According to the data analysis result obtained through various tests and simulations, the pattern size of the assist feature adaptable for the ArF process is less than 35 nm. However, the mask manufacturing company cannot deal with the assist feature having the above pattern size. Actually, the mask manufacturing company cannot inspect the assist feature having the pattern size adaptable for the ArF process.

In the meantime, there has been suggested another method for ensuring a process margin without using the assist feature by enlarging a size of an outermost pattern. However, according to the above method, inner patterns of the pattern region may have irregular CDs, so that it is difficult to use the above method in practice.

### SUMMARY OF THE INVENTION

Accordingly, the present invention has been made to solve the above-mentioned problems occurring in the prior art, and an object of the present invention is to provide a photo mask for fabricating a semiconductor device, which can ensure a process margin for a photo process without using an assist feature by changing a design of an outermost pattern.

Another object of the present invention is to provide a photo mask for fabricating a semiconductor device, capable of ensuring a process margin without using an assist feature.

In order to accomplish the above objects, according to the present invention, there is provided a photo mask used for fabricating a semiconductor device, the photo mask comprising: a line/space pattern part for forming a line/space pattern on a wafer, wherein the line/space pattern part includes an outermost pattern having a slice pattern so that the outermost pattern of the line/space pattern part is divided into two or more pattern segments.

According to the preferred embodiment of the present invention, the outermost pattern includes an inner pattern, the slice pattern and an outer pattern.

The inner pattern has a size smaller than a size of the outer sliced pattern.

The slice pattern has a size of about 20 to 90 nm. Preferably, the slice pattern has a size of about 40 to 50 nm.

### BRIEF DESCRIPTION OF THE DRAWINGS

The above and other objects, features and advantages of the present invention will be more apparent from the following detailed description taken in conjunction with the accompanying drawings, in which:

FIG. 1 is a view illustrating a conventional photo mask having an assist feature used for fabricating a semiconductor device;

FIG. 2 is a view illustrating a photo mask for fabricating a semiconductor device according to one embodiment of the present invention; and

FIG. 3 is a view illustrating a simulation result obtained through a HOST simulator according to one embodiment of the present invention.

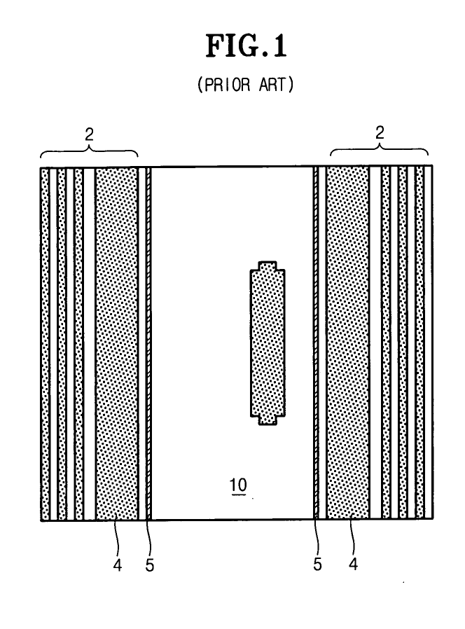

### DETAILED DESCRIPTION OF THE PREFERRED EMBODIMENTS

Hereinafter, the present invention will be described with reference to accompanying drawings.

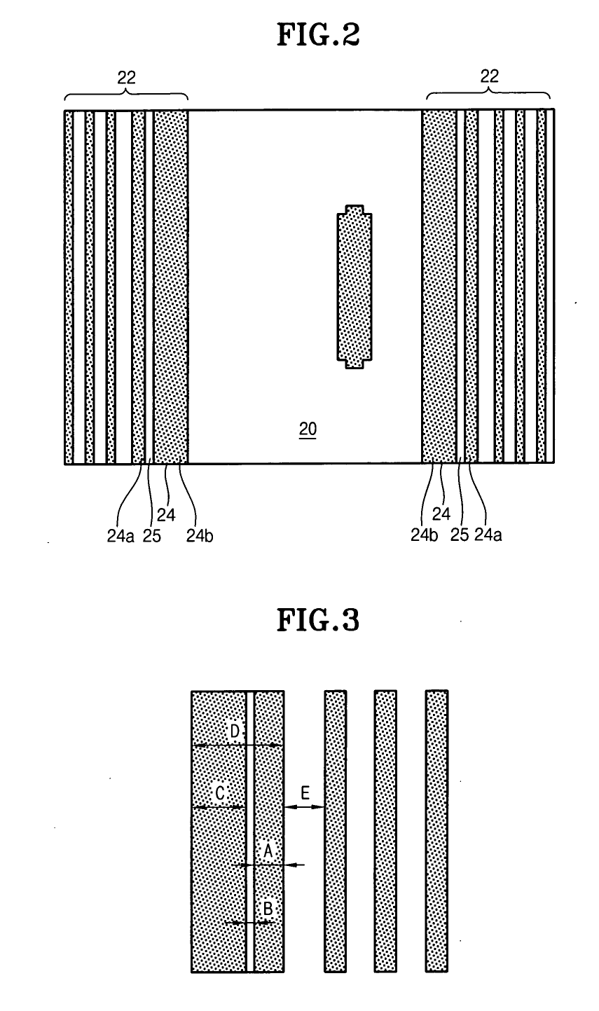

FIG. 2 is a view illustrating a photo mask 20 for fabricating a semiconductor device according to one embodiment of the present invention.

The photo mask 20 of the present invention is used for forming an L/S pattern, such as a DSL and an SSL of a flash memory device, on a wafer. As shown in FIG. 2, the photo mask 20 includes an L/S pattern part 22 including an outermost pattern 24 having a slice pattern 25 so that the outermost pattern 24 is divided into two or more pattern segments.

In general, the outermost pattern 24 of the L/S pattern part 22 has a CD larger than a CD of an inner pattern. However, according to the present invention, the outermost pattern 24 includes the slice pattern 25 so that the outermost pattern 24 is divided into two or more pattern segments. At this time, the slice pattern 25 has a space of about 20 to 90 nm. In a case of a photo mask used for an ArF exposure process, the slice pattern 25 preferably has a space of about 40 to 50 nm.

In FIG. 2, reference numerals 24a and 24b represent inner and outer patterns of the outermost pattern 24, respectively.

Thus, according to the present invention, the size of a mask pattern formed on the wafer corresponding to the outermost pattern 24 of the photo mask 20 can be reduced, so that the CDs of the inner patterns can be uniformly formed and the DOF of the photo process can be improved by 0.05 to 0.1 μm.

If the outermost pattern 24 has no process margin, the CD of an outer area having a wide space may be greatly reduced according to variation of the focus, so that the CD of the outer area may deviate from a reference level or the pattern may be collapsed. However, according to the present invention, the outermost pattern 24 is divided into at least two pattern segments by means of the slice pattern 25. Therefore, the CD of the outermost pattern 24, which is being reduced, may be no more reduced in the vicinity of the slice pattern 25, so that variation of the CD may be significantly reduced.

Therefore, the photo mask according to the present invention can ensure the process margin for the outermost pattern of the L/S pattern formed on the wafer without using the assist feature while improving CD uniformity of the inner patterns of the L/S pattern.

FIG. 3 and Table 1 illustrate a simulation result obtained through a HOST simulator under the condition identical to that of the DSL region or the SSL region of the flash memory device.

Referring to FIG. 3 and Table 1, a base line shows a general method for ensuring the process margin by enlarging the size of the mask pattern formed on the wafer corresponding to the outermost pattern of the photo mask without using the assist feature. According to this method, CD variation (ΔCD) according to focus variation of the outermost pattern has a relatively high value of about 24 nm.

In contrast, if the outermost pattern of the L/S pattern part formed in the photo mask is divided into at least two pattern segments according to the present invention, CD variation (ΔCD) according to focus variation of the outermost pattern is of about −1 to 7 nm, which is smaller than that of the conventional CD variation by about 20 nm.

TABLE 1

| | | |
|---|---|---|
| Pattern size(L/S) | E: adjacent | CD |

| | A: Line | B: slice | D: Line | pattern | | | variation |
|---|---|---|---|---|---|---|---|
| Test | (nm) | CD(nm) | (nm) | distance | F = 0.0 μm | F = 0.1 μm | (ΔCD) |
| Base | 0 | 0 | 298 | 130 | 97 | 73 | 24 |
| Line | | | | | | | |
| 1 | 74 | 40 | 298 | 100 | 66 | 59 | 7 |
| 2 | 74 | 40 | 328 | 100 | 83 | 80 | 3 |
| 3 | 100 | 40 | 278 | 100 | 70 | 67 | 3 |
| 4 | 110 | 40 | 288 | 80 | 51 | 50 | 1 |
| 5 | 80 | 40 | 278 | 80 | 65 | 66 | −1 |
| 6 | 80 | 40 | 278 | 100 | 76 | 74 | 3 |
| 7 | 80 | 40 | 278 | 110 | 93 | 87 | 5 |

As described above, according to the present invention, the mask pattern of the photo mask corresponding to the outermost pattern of the L/S pattern region of the wafer is divided into two or more pattern segments, so that it is possible to ensure the process margin for the outermost pattern without using the assist feature when forming the outermost pattern.

In addition, since the photo mask of the present invention does not use the assist feature, process limitations caused by the assist feature can be removed, so that the process margin for the exposure process may be easily ensured.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A photo mask used for fabricating a semiconductor device, the photo mask comprising:
a line/space pattern part for forming a line/space pattern on a wafer, wherein the line/space pattern part includes an outermost pattern having a slice pattern so that the outermost pattern of the line/space pattern part is divided into two or more pattern segments.

2. The photo mask as claimed in claim 1, wherein the outermost pattern includes an inner pattern part, the slice pattern, and an outer pattern part.

3. The photo mask as claimed in claim 2, wherein the inner pattern part has a size smaller than a size of the outer pattern part.

4. The photo mask as claimed in claim 1, wherein the slice pattern has a size of about 20 to 90 nm.

5. The photo mask as claimed in claim 4, wherein the slice pattern has a size of about 40 to 50 nm.

6. The photo mask as claimed in claim 1, wherein the slice pattern has a linear shape.
